(19) United States
(12) Patent Application Publication
(10) Pub. No.: US 2007/0061637 A1
(43) Pub. Date: Mar. 15, 2007

(54) Process for conducting high-speed bitmapping of memory cells during production

(75) Inventors: Mark A. Ward, West Linn, OR (US); Jeff Earl Conder, Sandy, OR (US)

Correspondence Address: LSI LOGIC CORPORATION, 1621 BARBER LANE, MS: D-106, MILPITAS, CA, 95035, US

(73) Assignee: LSI Logic Corporation

(21) Appl. No.: 11/225,606

(22) Filed: Sep. 12, 2005

(51) Int. Cl. G11C 29/00

(52) U.S. Cl. 714/718

(57) ABSTRACT

The present invention is directed to a method of fast bitmapping defective memory arrays in semiconductor integrated circuit dice formed on a wafer. The method involves loading a wafer onto automated test equipment. Initial production testing is then performed on each die of the wafer to determine whether the memory arrays of each die are functioning properly. Where a die is found to have at least one defective memory array, the particular memory arrays of the die that contain defect are specifically identified using BIST circuitry forming part of the die. Then selectively performed diagnostic testing is performed on only the failed memory arrays of each defective die to generate memory array defect data. The memory array defect data is used to generate bit maps of the failed memory arrays using the memory array data.

### FIELD OF THE INVENTION

The invention described herein relates generally to methods and processes for conducting fast bit mapping of defective memory locations on semiconductor integrated circuits. Among other things, the technology finds applicability to fast bit mapping of defective memories on semiconductor integrated circuits in both packaged and wafer forms.

### BACKGROUND OF THE INVENTION

In the semiconductor industry it is common to test integrated circuit (IC) devices during fabrication to insure that they are functional. Currently a wide variety of testing processes are used to conduct such testing. The invention disclosed herein introduces improved methods and apparatus for testing such IC devices.

As is known to those having ordinary skill in the art IC's are manufactured on semiconductor wafers (typically formed of silicon or other semi-conducting substrates). A number of IC devices are formed on each wafer with the number of IC devices formed being a factor of the size of the device and the size of the wafer. It is common to form hundreds of IC devices on a single wafer. Each one of these devices is commonly referred to as an IC chip or alternatively as a die.

Due to the potential for (and indeed the common occurrence of) fabrication defects each die so fabricated must be tested to insure adequate functionality. Each die is tested by running a series of tests using automatic test equipment. These tests are designed to identify dice that pass all the device electrical specifications and to reject die which do not meet the electrical specifications. Such tests are carried out on each die on a silicon wafer (Wafer Test) and then repeated on a fully packaged IC (Final Test).

One such test includes a test of on chip memory functionality. This is a useful test for a number of reasons. Memory requires a high density of active elements (i.e., transistors) and therefore fabrication defects are very likely to show up in memory areas first. Additionally, in more modem designs, memory is taking up larger and larger portions of the space on each die.

As is known, memories are regular arrays of transistors that are used to store data in an IC. An example of one representative type of such memory is Static Random Access Memory (SRAM). The inventors point out that the invention is not intended to be limited to SRAM implementations only, but can be broadly applied to all types of memory. During production testing of an IC, the memories are tested using test routines built into the IC. These test routines determine if the memory passes the specification or is rejected. Typically, these routines are designed for optimum test coverage by writing and reading many different test algorithms into a memory array. They are also optimized for testing at the fastest test time and the output of such production memory testing is pass or fail only.

In one current process, a wafer is tested on Automated Test Equipment (ATE). Typical examples of such test equipment are a T6672 ATE Machine produced by Advantest Corporation of Tokyo, Japan or Vista, Quartet, and Octet machines produced by Credence Systems Corporation of Milpitas, Calif. Many other manufacturers and machine types are known to those of ordinary skill in the art.

A simplified example of a testing method currently used in the industry is now described to illustrate certain shortcomings in present diagnostic methods. Commonly, a test pattern of data is read into each die to test each memory bit in the die. For example, a series of “ones” is written into the memory of a die and then all the memory bits are read out from the dice. In a fully functional dice the data in will be the same as the data out. Thus, if the read out data bits are also all “ones”, then the die passes. This is done for each die on a wafer. If there is any variance between the data read into the die and the data read out of the die, then there is a defect in the die.

The next step is to identify where the defect is on the wafer. This is a much more difficult and time-consuming process. Using currently employed methods a “production test” is performed on each defective die. As memories are regular dense arrays, bitmapping is a technique used to identify failing bit cells. By applying specific test patterns to the memory array and then reading back the stored data and comparing it to the expected data, faulty bit cells can be identified. These faulty cells can then be mapped against their physical location in the memory array and analysis tools can then determine potential fault mechanisms based on the failing pattern signatures. Some typical examples include Single Column failure faults, Multiple Column failure faults, Single Bit failure faults, Row failure faults, Clustering Bits failure faults, and so on. One aspect of this test is to run a bit map diagnostic routine on each failed die. This means that a bit map is generated that examines every bit of memory on a die. Considering that some die can have more than 100 memory instances each having up to a million or more bits or more of memory, this can take some time. On the positive side such memory bitmapping is useful for analyzing the causes of defects and helpful in improving yield as memory arrays are generally much denser than standard logic area's. This is especially useful if such bit mapping can be done at real-time as information learned can be directly applied to fabrication processes during production.

However, balanced against the obvious utility of such bitmapping processes are the following drawbacks. Such production memory testing is normally carried out through on chip self-test algorithms. These algorithms are optimized for the test coverage (completeness) and the rapid test times. Consequently, these algorithms only provide pass or fail information. Traditional bitmapping takes a substantial amount of time. On average, bitmapping all memories of all failed die on a single wafer takes 1.5-2.5 hours in addition to the normal time used for testing the wafer. Thus, traditional bitmapping represents at least a tenfold time increase over standard pass/fail testing. Due to the substantially increased test time and the associated cost (due to delays, process bottlenecking, and additional engineering time involved) such bitmapping is generally only performed on a sampling basis and only of the lowest yielding wafers (i.e., the wafers resulting in the lowest percentage of acceptable die). Moreover, the time required to write each and every data bit from all the memory of a failed die is exorbitant. This is important because all processing is put on hold until such data is collected and then read to an analysis file.

For these reasons bitmapping is usually carried out under engineering control and limited to a sampling basis. This means that only some of the manufactured wafers can be bitmapped. In the past only the poorest yielding wafers were bitmapped. Thus, the ability to seriously examine memory on a regular basis during processing has been denied to process engineers. The inventors have recognized that these limitations of the existing techniques seriously impact their usefulness. There is a need for improving bit mapping techniques and approaches. The invention described herein discloses method and apparatus for enabling faster bitmapping and improved IC testing.

### SUMMARY OF THE INVENTION

The principles of the present invention disclose a method for fast bitmapping memory instances in a semiconductor IC die.

In one embodiment, the invention describes a method for fast bitmapping defective memory arrays in semiconductor integrated circuit dice formed on a wafer. The method involves providing automated test equipment and loading a wafer onto the automated test equipment. Initial production testing is performed on each die of the wafer to determine whether all of the memory arrays of each die are functioning properly. Where a die is found to have at least one defective memory array, the particular memory arrays of the die that contain defect are identified. Then selective diagnostic testing is performed on only the failed memory arrays of each defective die to generate memory array defect data. The memory array defect data is used to generate bit maps of the failed memory arrays using the memory array data.

In another embodiment, the method of the invention describes a method for fast bitmapping defective memory arrays in a semiconductor integrated circuit device. Such method includes providing a die having N memory arrays with built-in self repair (BISR) logic and a built-in self test (BIST) capable of identifying whether each specific memory array contains defects. This die is subjected to initial production testing of all N memory arrays to determine whether they are all functioning properly. Where a memory array is found to be defective in a die, identifying which particular memory arrays contain defects. Then diagnostic testing is selectively performed only on the failed memory arrays to generate memory array defect data which is then used to generate bit maps of the failed memory arrays.

In another embodiment the invention describes a computer program product having computer program code for fast bitmapping defective memory arrays in semiconductor integrated circuit dice formed on a wafer. The program includes instructions for conducting initial production testing is performed on each die of the wafer to determine whether all of the memory arrays of each die are functioning properly. Where a die is found to have at least one defective memory array, the program includes instructions for identifying the particular memory arrays of the die that contain defects. Then instructions for selectively performing diagnostic testing are executed only on the failed memory arrays of each defective die to generate memory array defect data. The program includes instructions for generating a data file used to create bit maps of the failed memory arrays using the memory array data

These and other features and advantages of the present invention are described below with reference to the drawings.

### BRIEF DESCRIPTION OF THE DRAWINGS

The following detailed description will be more readily understood in conjunction with the accompanying drawings, in which:

FIG. 1 is a simplified schematic depiction of a semiconductor IC die having a plurality of memory instances formed thereon.

FIG. 2 is a simplified schematic depiction of an example memory instance showing BISR and BIST circuitry in accordance with the principles of the invention.

FIG. 3 is a simplified flow diagram illustrating a process flow usable by embodiments of the present invention.

FIG. 4 is a simplified schematic depiction of a system for fast bitmapping a semiconductor wafer in accordance with the principles of the invention.

It is to be understood that, in the drawings, like reference numerals designate like structural elements. Also, it is understood that the depictions in the Figures are not necessarily to scale.

### DETAILED DESCRIPTION

The present invention has been particularly shown and described with respect to certain embodiments and specific features thereof. The embodiments set forth hereinbelow are to be taken as illustrative rather than limiting. It should be readily apparent to those of ordinary skill in the art that various changes and modifications in form and detail may be made without departing from the spirit and scope of the invention.

In general terms the following discussion concerns methods, apparatus, and computer program products for conducting fast bitmapping of memory instances during production. In one general approach, a production test of each die on a semiconductor wafer is performed. The test is intended to be performed on die having a plurality of memory instances supported with built-in self repair (BISR) functions. Such memory repair functionality includes built-in self test (BIST) functions for determining if selected memory instances are defective. So in addition to detecting if a die has defective memory, the inventive production test can also determine which of the memory instances are defective using the BIST functionality. After identifying which memory instances are defective, diagnostic testing is selectively performed only on the defective memory instances instead of all memory instances as in the prior art. This selective information forms a much smaller data set than the prior art bitmaps which map all memory spaces on a die. Because the new selective data sets are so much smaller than that of the prior art, they can be quickly downloaded and/or reviewed. This makes it so that, if desired, such bitmapping can be performed in real time on all wafers not just selected wafers as is now the case. This presents a substantial improvement in collecting defect data and troubleshooting manufacturing processes. This disclosure provides methods for accomplishing this goal.

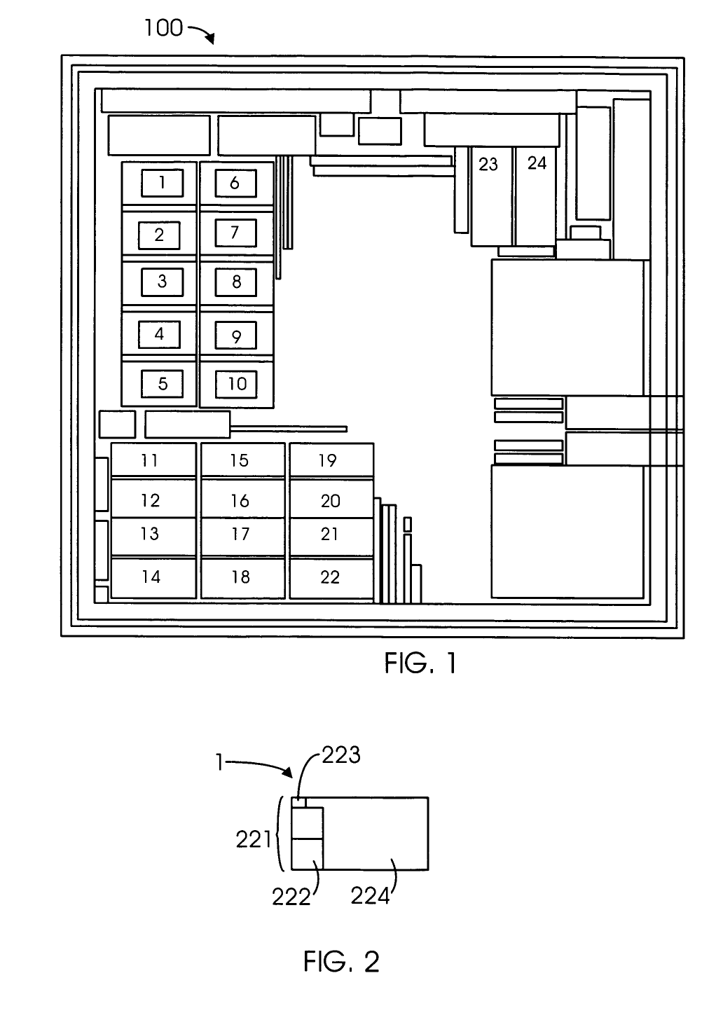

FIG. 1 is a simplified depiction of an example semiconductor die 100. Such die contain thousands of logic circuits. Additionally, such die contain many memory fields (also referred to herein as memory “instances”). Such fields are spaces of the die that are devoted to memory. Commonly such fields comprise memory arrays. With each succeeding generation of integrated circuit design, a larger and larger portion of the circuitry of the die are devoted to memory array. Additionally, the size of individual memory arrays are also growing. It is now common to have dozens of memory arrays per die with each of the arrays comprising thousand or even millions of memory bits. The depicted die 100 is shown with 24 schematically depicted memory arrays (arrays 1-24) at various locations on the die.

Each such memory array is generally comprised of thousands of rows and columns of transistors that operate together to function as a memory space. The very tight fabrication tolerances of manufacture for such memory circuitry when coupled with the less than perfect manufacturing technique that is the current state of the art, leads to the occasional failure of some of the memory bits of the memory circuitry. For that reason it is common to add “back-up” (or redundant) rows and columns to the memory arrays. When it is discovered that row or column of transistors contains a defect, one of the back-up rows or columns is employed as a replacement. The marginal cost of adding a few extra rows and columns to each memory array is far outweighed by the costs of scrapping the entire die for a single memory failure.

In order to implement the back-up memory rows and columns, specialized circuitry is added to each memory array to identify and diagnose memory failure and implement the back-up memory to keep the memory array operational despite the local failure of some memory elements. The common name given to this type of circuitry is built-in self repair (BISR). As stated above, BISR identifies the presence of defects and employs one or more of the available extra memory rows or columns to circumvent the defective memory elements. One portion of the BISR is a built-in self test (BIST) which is specialized to identify the presence of defects. BIST can identify, with some degree of precision, the nature of the identified defect. BIST can also be employed as a go/no go test which can identify whether a memory array has defects or not. Such a pass or fail test can be simply reflected by a single pass/fail bit for each memory instance. Thus, among other things, the BIST can provide a quick one-bit pass/fail analysis of a memory space.

This is briefly depicted in FIG. 2 which is a schematic depiction of one example memory space 1. The memory space 1 includes BISR circuitry 221 containing BIST circuitry 222 and a pass/fail bit 223. The rest of the memory space includes a memory array 224 having a plurality of rows and columns of transistors.

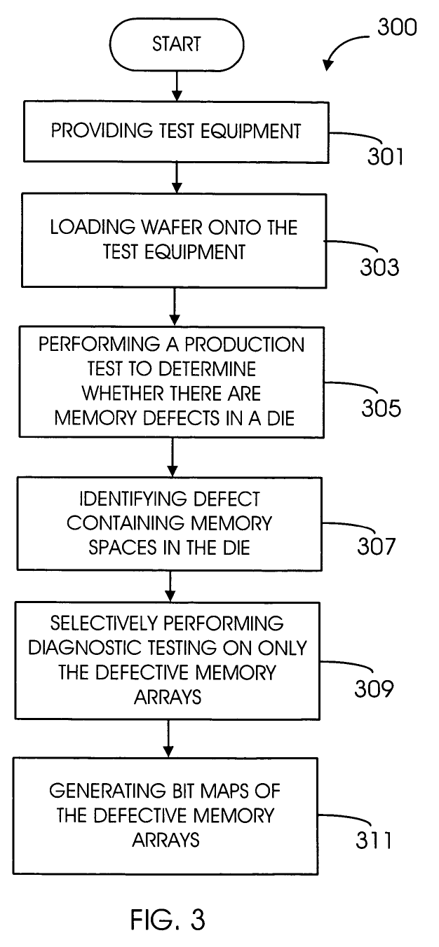

Embodiments of the present invention take advantage of the presence of the BIST to enhance memory bitmapping in a way not possible before. FIG. 3 is a flow diagram 300 illustrating one embodiment for implementing the principles of the invention. The depicted flow diagram discloses a memory test method for fast bitmapping defective memory arrays in semiconductor integrated circuit dice formed on a wafer. Automated test equipment capable of evaluating semiconductor wafers is provided (Step 301). Such equipment is known to those having ordinary skill in the art. Example include but are not limited to T6672 ATE Machines (from Advantest Corporation of Tokyo, Japan) or Vista, Quartet, and Octet machines (from Credence Systems Corporation of Milpitas, California), as well as many other machines capable of automatic testing of wafers. The wafers are loaded onto the automated test equipment (Step 303). The wafers in question wafer have a number of semiconductor integrated circuit dice formed on them. Additionally, each die has at least one but generally many memory arrays. Each die is configured to include built-in self repair (BISR) logic. Moreover, the BISR includes a built-in self-test (BIST) capable of identifying whether each specific memory array contains defects. The details of such BISR and BIST circuitry are known in the art and need not be discussed in detail here.

Once the wafer is loaded and the system is initialized for operation and the inspection test program is entered into the ATE testing can begin. An initial production test is performed on each die on the wafer to determine whether all of the memory arrays of each die are functioning properly (Step 305). As is known to those having ordinary skill in the art, the initial production test can be accomplished in a number of different ways. For example a known data pattern of data bits can be read into the die and then the data is read out of the die and a comparison of data in is made with data out. If the two data sets are the same, then all memory arrays on a die are defect free and determined to be functioning properly and the die passes this memory test and no further memory inspection is needed for this die. This test is performed for each die on the wafer. This is generally a pass/fail type test and is performed very quickly.

However, some memory bits may be found that have defects. This may not cause failure of the die but it does indicate that there are some imperfections in the memory spaces somewhere. For each die found having one defective memory bit it is known that at least one memory array is defective. In this case, the inventors understand “defective” to mean contains a non-functioning memory bit rather than completely non-functional. However, defect containing memory arrays can be non-functional. In any case, once a die is determined to have defective memory bits, the question becomes, where are the defective bits. Thus, the method involves identifying, in each die having at least one defective memory bit, which particular memory arrays of the die contain defects (Step 307). In one embodiment this identification process involves running the BIST to identify each memory instance having defects therein. In an advantageous alternative embodiment, the defective arrays can be identified as part of the initial production test (Step 305) by referring to the go/no go bits (223) of each memory instance. These bits quickly identify which memory instances contain defects. Accordingly this method represents a quick process by which all defect containing memory spaces can be identified. For each die, these defect containing memory spaces are identified and the specific defective memory array locations can be stored for further analysis as described below.

The following sub-routine presents one example of method of performing the appropriated tests. For each die having “m” BISR enabled memory blocks the following procedure can identify failed memory instances. Where m0 reflects the “m” block pattern and can be changed to reflect the naming of each of the “m” memory blocks. This procedure determines which memory instance has failed so that an appropriate flag can identify the failed memory instance. An example of a suitable piece of code follows:

int bitmap_m0(MEASURE_FT measure)
{
/************************************************/
/* AC RAM BITMAP M0 */
/************************************************/
DFM dfm;

| | |
|---|---|
| long long int fcnt; | //failure count |
| long long int max_fcnt; | //number of highest failure to record |
| int max_dfm=256; | //max hardware DFM memory 1023 for T6683 and 256 for others |

ARRAY<long long int> pcnt(max_dfm); //array to store pattern cnt of failures

| | |
|---|---|
| ARRAY<int> ste(max_dfm); | //array to store STE of failures |

int pass = 1;
int index;
int max_index;
TEST.desc(“ M0 BLK BITMAP TEST”);
TEST.id(295);
TEST.pg(NORMAL);
TEST.Set( );
dfm.type(DFM_FAILSTORE);
datalog_bitmap_set( ); //enable datalog output to data collection file (same as stdf)
do
{

| | |
|---|---|
| max_fcnt=pass*max_dfm; | //max failure to store is DFMsize*pass |
| dfm.fcnt(max_fcnt); | //set DFM limit to max_fcnt |
| dfm.Load( ); | //set DFM |

sequence.PreExec( );

| | |
|---|---|
| measure.Exec( ); | //collect failing vector locations |

```
  fcnt=measure.Get_FcntLong( );
  measure.Get_RpcntLong(0, pcnt, max_dfm);
  measure.Get_Ste_addr (0, ste, max_dfm);
  if (fcnt>max_fcnt) max_index=max_dfm; //store all DFM failures
  else max_index=int(fcnt % max_dfm);  //store last failures
  for (index=max_index −1; index>=0; index−−) {
    // Index to inst_map is the memory controller BP #
    if (pcnt[index]==250763) inst_map(92); // ram5a
    if (pcnt[index]==250791) inst_map(93); // ram5b
    if (pcnt[index]==250819) inst_map(94); // ram6a
    if (pcnt[index]==250847) inst_map(95); // ram6b
    if (pcnt[index]==251071) inst_map(103); // ram10b
    if (pcnt[index]==251099) inst_map(104); // ram11a
    if (pcnt[index]==251127) inst_map(105); // ram11b
    print pcnt[index], “\t”, ste[index], “\n”; //print for debugging
    }
  pass++;
}while(max_fcnt<=fcnt);
dc_setup.clear_il( );
  datalog_bitmap_reset( ); // disable datalogger data collection
  return 0;
} // end of bitmap_m0
```

Once the defective memory spaces are identified, special diagnostic testing is selectively performing on only the failed memory arrays of each defective die as identified previously (Step 309). The special diagnostic testing require engineering diagnostics programs having special memory diagnostic patterns which better allow bitmapping of the memory arrays. These patterns are usually generated in. WGL test pattern format and include tests for all memory instances. A few example patterns used to accomplish such testing are discussed below.

In the following code, a “for” loop is used. Each item in the pcnt[ ] array is compared against a vector location. The array contains the failing vector locations for the last executed “m” block. These vector locations can be entered from a spreadsheet provided by design, or may be available in the “m” block wgl file. For every instance that is tested in this particular “m” block pattern there is one corresponding vector location. To determine the vector location for each instance, the spreadsheet is consulted for a GO bit vector location that matches with an instance in the appropriate “m” block. A unique ID is then provided to the inst_map( ) procedure to identify which instance has failed. In this example, a BP controller number is used as the identifier, comments are also included to identify which memory instance has failed. Many memory instances can be tested in one “m” block pattern.

Where a vector location is contained in the “m” block wgl file, a UNIX command can be used to filter the wgl file for comments associated with these locations: awk /text1/,/text2/. Where text1 is “core” or some other text that is common in the instance name, text2 is a terminating string in the search and can be “cycle”. This extracts all occurrences of lines between these two texts and the vector cycle number would be part of the comment. This is only valid if the design center has updated the wgl file to contain this info, otherwise it should be part of the spreadsheet provided.

| | Bisr Reset | Bisr Reset |
|---|---|---|
| Memory Inst | (ns) | (vector) |
| u_core_0.cm.bm_bisr_ram0a_GO_unmask | 2329482.6 | 250482 |
| u_core_0.cm.bm_bisr_ram0a_GO_mask | 2329491.9 | 250483 |
| u_core_0.cm.bm_bisr_ram0a_DONE_unmask | 2329612.8 | 250496 |
| u_core_0.cm.bm_bisr_ram0a_DONE_mask | 2329622.1 | 250497 |
| u_core_0.cm.bm_bisr_ram0b_GO_unmask | 2329743 | 250510 |
| u_core_0.cm.bm_bisr_ram0b_GO_mask | 2329752.3 | 250511 |
| u_core_0.cm.bm_bisr_ram0b_DONE_unmask | 2329873.2 | 250524 |
| u_core_0.cm.bm_bisr_ram0b_DONE_mask | 2329882.5 | 250525 |
| u_core_0.cm.bm_bisr_ram1a_GO_unmask | 2330003.4 | 250538 |
| u_core_0.cm.bm_bisr_ram1a_GO_mask | 2330012.7 | 250539 |

### EXCEL FILE EXAMPLE

In the spreadsheet file example above, the instance name and corresponding vector number that can be used to build the pcnt[ ] array comparison table are in boldface text. The details of the spreadsheet are not standardized and can be varied from what is shown here.

The datalog₁₃ bitmap₁₃ set( ) and datalog₁₃ bitmap₁₃ reset( ) procedures called in code example 1 should be inserted into the test program prior to being called. This particular example can be used to enable the data collection facilities of the ATE in use. The following code contains these two procedures:

```
DATALOG bisrlog;
int datalog_status, datalog_result, datalog_type;
int bisrlog_enabled=1;
void datalog_bisr_reset( ) {
  if ((bisrlog_enabled == 1) && (stdf_enabled == 1 )){
    bisrlog.format(DTLOG_LONG);
    bisrlog.ft_format(DTLOG_H_FAILPIN);
    bisrlog.pin_display(DTLOG_OBJ);
    switch (datalog_type) {
```

| | |
|---|---|
| case 0 : break; | |
| case 1 : bisrlog.type( DC ); | break; |
| case 2 : bisrlog.type( FT ); | break; |
| case 3 : bisrlog.type( DC, FT ); | break; |
| case 4 : bisrlog.type( AC ); | break; |
| case 5 : bisrlog.type( DC, AC ); | break; |
| case 6 : bisrlog.type( FT, AC ); | break; |
| case 7 : | |
| default : bisrlog.type( DC, FT, AC ); | break; |

```
    }
    switch (datalog_result) {
```

| | |
|---|---|
| case 0 : break; | |
| case 1 : bisrlog.result( FAIL ); | break; |
| case 2 : bisrlog.result( PASS ); | break; |
| case 3 : | |
| default : bisrlog.result( FAIL, PASS ); | break; |

```
    }
    bisrlog.ft_pinlist(ALL);
    bisrlog.ft_type(DTLOG_CONTINUOUS_FAIL);
    bisrlog.ft_limit_dfm(ON);
    bisrlog.ft_fcnt(10);
    bisrlog.Enable( );
    bisrlog.Load( );
  }
}
void datalog_bisr_set( ) {
```

| | |
|---|---|
| datalog_status = bisrlog.Get_LogStatus( ); | // enabled, Bit 0 = 1; |
| disabled, Bit 0 = 0 | |
| datalog_result = bisrlog.Get_LogResult( ); | // Bit 0 = fail only; Bit |
| 1 = pass only | |
| datalog_type = bisrlog.Get_LogType( ); | // Bit 0 = DC; Bit 1 = |

```
FT; Bit 2 = AC
  if ((bisrlog_enabled == 1) && (stdf_enabled == 1)) {
    bisrlog.format(DTLOG_LONG);
    bisrlog.ft_format(DTLOG_H_FAILPIN);
    bisrlog.pin_display(DTLOG_OBJ);
    bisrlog.ft_pinlist(ALL);
    bisrlog.ft_type(DTLOG_CONTINUOUS_FAIL);
    bisrlog.ft_limit_dfm(OFF);
    bisrlog.ft_fcnt(0xffffffff);
        bisrlog.ft_radix(DTLOG_ADDR_DEC);
        bisrlog.ft_scan_info(ON);
    bisrlog.type(FT);
    bisrlog.result(FAIL);
    bisrlog.output(“/export/home/vpoint/report/temp.new”, “a”);
    bisrlog.Enable( );
    bisrlog.Load( );
  3-  }
```

Many other implementation examples and details can be employed to execute the principles of the invention. In any case, regardless of specific implementation details, the overall approach allows diagnostic testing to be performed on only the memory instances having defects. Thus, this presents a considerable time savings over the prior art methods. In the past, such diagnostic testing was performed on every memory bit in the entire die to identify the defective bits. With memory array containing upwards of a million memory bits per memory array, and with each die containing as many as one hundred memory arrays (or more), the time to do such diagnostic testing was enormous. In one typical example, to test a single wafer could take between 90 to 150 minutes. In the mean time, the ATE machine cannot be used for anything else. Moreover, expensive engineering time is spent waiting for and analyzing the diagnostic data. More problematic is the fact that, under most conditions, most of the diagnostic data contains little information of value because it pertains to memory spaces that have no defects. The present invention remedies these problems by only doing diagnostic testing on memory arrays known to have defects. Time is not wasted taking data from perfectly good memory arrays. For example, using the die of FIG. 1, if the die was understood to have memory defects, then all twenty-four memory spaces would be subject to diagnostic testing. 24 million data bits. In contrast, if say only memory arrays 2, 23, and 24 contain defects, diagnostic testing need be run only on the bits corresponding to arrays 2, 23, 24. This represents a huge saving of time. By way of example, using the principles of the present invention, the time spent generating memory array defect data in typical die is reduced to on the order of 10 minutes. This represents at least a ten-fold improvement over previously used methods. Finally, using the diagnostic memory array data generated during the testing, bit maps of the failed memory arrays are generated (Step 311).

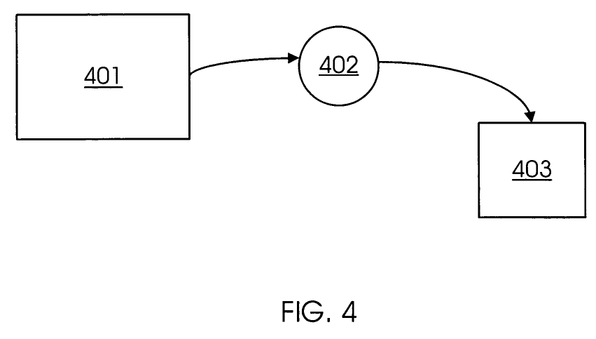

The advantage of such an approach now allows all wafers to be bitmapped and a continuous stream of defect information to be obtained throughout a production process without any serious interruption of process flows. FIG. 4 is an extremely simplified schematic depiction of a test system for use in accordance with the principles of the invention. A processing machine 401 processes an example wafer 402 which is then tested using automated test equipment 403.

The inventors point out that the forgoing method is commonly implemented as a computer program product that can be stored on a computer readable media and executed on a device capable of executing computer readable instructions.

The invention can use a combination of hardware and software components. The software can be embodied as computer readable code (or computer program code) on a computer readable medium. The computer readable medium is any data storage device that can store data which can thereafter be read by a computer system. Examples of the computer readable medium include read-only memory, random-access memory, CD-ROMs, magnetic tape, and optical data storage devices. The computer readable medium can also be distributed over a network coupled computer systems so that the computer readable code is stored and executed in a distributed fashion.

The inventors point out that certain embodiments of the invention provide a number of advantageous features not found in the prior art. The present invention provides very fast bitmapping times as not all memory instances are required to be bitmapped. These very fast times can be on the order of 10 minutes per wafer which is over ten times as fast as existing approaches. These very fast bit mapping times enable the invention to be implemented cost effectively in a production environment thereby further reducing cost and time overhead. Additionally, unlike existing methods, no specialized engineering intervention is required to collect bit mapping information. This enables the expense of engineering time to be concentrated on bitmap signature analysis instead of data collection. Because the bitmapping can be performed on many more wafers, a faster “yield learning rate” can be obtained which is enhanced by the “real-time” data collection possible using the present invention. The immediacy in feeding fail signature information back into the manufacturing process is a significant improvement enabling must faster yield correction. Also, wafer lots are not placed on production hold while data is being collected.

Some of the most advantageous novel features include only the defect containing memory instances are bitmapped rather than all memory.

It is novel to use the information collected during the BISR repair test to identify failing memory instances for bitmapping purposes. Another novel feature is the modification of the special diagnostic testing patterns to allow bitmapping of only the failing memory instances on a die by die basis during production testing. Normally the diagnostic patterns are used on all memory instances. Additionally, the diagnostic patterns can be modified in real time during each IC test based on the failing BISR information. And perhaps most advantageous of all, by significantly reducing the amount of data collected during bitmapping, the time to access and read to the data collection files is greatly reduced. Also the size of the data files that need to be stored and post processed is greatly reduced

The many features and advantages of the present invention are apparent from the written description, and thus, it is intended by the appended claims to cover all such features and advantages of the invention. Further, since numerous modifications and changes will readily occur to those skilled in the art, it is not desired to limit the invention to the exact construction and operation as illustrated and described. Hence, all suitable modifications and equivalents may be resorted to as falling within the scope of the invention.

The present invention has been particularly shown and described with respect to certain embodiments and specific features thereof. However, it should be noted that the above-described embodiments are intended to describe the principles of the invention, not limit its scope. Therefore, as is readily apparent to those of ordinary skill in the art, various changes and modifications in form and detail may be made without departing from the spirit and scope of the invention as set forth in the appended claims. Further, reference in the claims to an element in the singular is not intended to mean “one and only one” unless explicitly stated, but rather, “one or more”.

What is claimed is:

1. A memory test method for fast bitmapping defective memory arrays in a semiconductor integrated circuit device, the method comprising:
a) providing a die having N memory arrays (where N comprises an integer value greater than zero) with built-in self repair (BISR) logic and including a built-in self test (BIST) capable of identifying whether each specific memory array contains defects;
b) initial production testing of all N memory arrays to determine whether all the N memory arrays are functioning properly, if all memory elements determined to be functioning correctly no further testing of the die is required;
c) alternatively, where at least one memory array is found to be defective, identifying which particular memory arrays contain defects;
d) selectively performing diagnostic testing only on the failed memory arrays to generate memory array defect data; and
e) creating bit maps of the failed memory arrays using the memory array data.

2. The memory test method of claim 1 wherein identifying which particular memory arrays contain defects comprises part of the initial production testing of all N memory arrays.

3. The memory test method of claim 2 wherein c) identifying which particular memory arrays contain defects comprises executing the BIST for each of the N memory arrays to identify the particular memory arrays that contain defects.

4. The memory test method of claim 3 further including the operation of troubleshooting a die fabrication process by using the bit maps of the failed memory arrays.

5. The memory test method of claim 3 wherein d) selectively performing diagnostic testing includes writing the memory array defect data to a file that can be downloaded.

6. The memory test method of claim 5 wherein the memory array defect data is downloaded into an analysis tool that enables the defect data to be analyzed at a different time than when the data is collected and wherein the analysis tool is used to accomplish operation e) creating a bitmap of the failed memory arrays using the memory array data.

7. The memory test method of claim 5 wherein the memory array defect data is downloaded into a different analysis tool than a tool used to perform the diagnostic testing.

8. A memory test method for fast bitmapping defective memory arrays in semiconductor integrated circuit dice formed on a wafer, the method comprising:
a) providing automated test equipment capable of evaluating semiconductor wafers;
b) loading a wafer onto the automated test equipment, the wafer having formed thereon a plurality of semiconductor integrated circuit dice, each die having memory arrays and built-in self repair (BISR) logic, the self repair logic including a built-in self test (BIST) capable of identifying whether each specific memory array contains defects;
c) performing initial production testing of each die on the wafer to determine whether all of the memory arrays of each die are functioning properly, where all memory arrays on a die are determined to be functioning properly no further testing of that die is needed;
d) for each die is found to have at least one defective memory array, identifying which particular memory arrays of the die contain defects;
e) selectively performing diagnostic testing only on the failed memory arrays of each defective die to generate memory array defect data; and
f) creating bit maps of the failed memory arrays using the memory array data.

9. The memory test method of claim 8 wherein d) identifying which particular memory arrays contain defects forms part of c) the initial production testing of each die.

10. The memory test method of claim 8 wherein d) identifying which particular memory arrays of the die contain defects includes executing the BIST for each of the memory arrays of each die to identify the particular memory arrays that contain defects.

11. The memory test method of claim 10 further including an operation of troubleshooting a die fabrication used to form the die on the wafer by using the bit maps of the failed memory arrays.

12. The memory test method of claim 10 wherein e) selectively performing diagnostic testing on only the failed memory arrays includes writing the memory array defect data to a file that can be downloaded.

13. The memory test method of claim 12 wherein the memory array defect data is downloaded into another analysis tool other than the automated test equipment which operations a) through e) are performed and wherein the another analysis tool is used to create the bitmap of the failed memory arrays at a later time without using the automated test equipment.

14. A computer program product embodied on a computer readable media including computer program code for executing a memory test method enabling fast bitmapping of defective memory arrays in semiconductor integrated circuit dice formed on a wafer, the program product including:
computer program code instructions for executing initial production testing of each die on the wafer to determine whether all of the memory arrays of each die are functioning properly, wherein each wafer has been loaded onto automated test equipment and the testing is executed by the automated test equipment and wherein the wafer has a plurality of semiconductor integrated circuit dice with each die having memory arrays and built-in self repair (BISR) logic, the self repair logic including a built-in self test (BIST) capable of identifying whether each specific memory array contains defects;
computer program code instructions for identifying specific defective memory arrays and thereby, for each failing die, identifying which particular memory arrays of the die contain defects for that die;
computer program code instructions for selectively performing diagnostic testing only on the failed memory arrays of each defective die to create memory array defect data; and
computer program code instructions for generating data suitable for forming bit maps of the defect patterns of the wafer using the results of the diagnostic testing.

15. The memory test method of claim 14 wherein the computer program code instructions for identifying specific defective memory arrays includes executing the BIST for each of the memory arrays of each die to identify the particular memory arrays that contain defects.

16. The memory test method of claim 15 wherein the computer program code instructions for selectively performing diagnostic testing only on the failed memory arrays of each defective die to generate memory array defect data includes instructions for downloading the results of the diagnostic testing to a file.

17. The memory test method of claim 16 wherein the computer program code instructions for generating data suitable for creating bit maps of the defect patterns of the wafer include instructions for reading the results of said diagnostic testing from the file and then using the results of the diagnostic testing to generate bit maps of the defect patterns.
